(19) United States
(12) Patent Application Publication
(10) Pub. No.: US 2024/0213692 A1
(43) Pub. Date: Jun. 27, 2024

(54) ELECTRICAL BUSBAR DEVICE

(71) Applicant: MAHLE International GmbH, Stuttgart (DE)

(72) Inventors: Tihomir Angelov, Ludwigsburg (DE); Oliver Fritz, Aichtal (DE); Achim Gommel, Weil der Stadt (DE); Volker Kirschner, Muehlacker (DE); Hans Christian Uibeleisen, Backnang (DE)

(21) Appl. No.: 18/393,647

(22) Filed: Dec. 21, 2023

(30) Foreign Application Priority Data
Dec. 22, 2022 (DE) 10 2022 214 321.3

(51) Int. Cl. H01R 4/36; H01R 43/02; H01R 43/26; H05K 1/02

(52) U.S. Cl. CPC H01R 4/36; H01R 43/0256; H01R 43/26; H05K 1/0263; H05K 2201/10272

(57) ABSTRACT

An electrical busbar device is disclosed. The busbar device includes an electrically conductive busbar for being flowed through by an electric current. At least one contacting element structured separately with respect to the busbar is provided. The contacting element is connected electrically and mechanically to the busbar. The contacting element is electrically conductive for connecting the busbar to a circuit board. The contacting element is fastened to the busbar via a screw connection and electrically connected to the busbar.

### CROSS-REFERENCE TO RELATED APPLICATION

This application claims priority to German Patent Application No. 10 2022 214 321.3 filed on Dec. 22, 2022, the contents of which are hereby incorporated by reference in their entirety.

### TECHNICAL FILED

The invention relates to an electrical busbar device and to an arrangement having such a busbar device. Further, the invention relates to a method for producing such an arrangement.

### BACKGROUND

In modern motor vehicles, in particular with electric drive, electric power components, in particular power semi-conductors such as for example power transistors, are often installed on circuit boards. It is usual to transport the high electric currents that occur during the operation with the help of so-called electrical busbars. Often, such busbars are soldered via so-called solder tails to the respective circuit board.

Such conventional busbars are described for example in DE 10 2009 029 476 A1.

Because the cross-section of the busbar which is often relatively large in practice, the soldering of the solder tails moulded on the busbar to the circuit board proves to be difficult or even impossible.

### SUMMARY

It is therefore an object of the present invention to show new ways in the development of the electrical busbars explained at the outset.

This object is solved through the independent patent claim(s). Preferred embodiments are subject of the dependent patent claims.

Accordingly, the basic idea of the invention is to configure a solder tail mentioned at the outset—in the following also referred to as “contacting element”—and the busbar not in one piece but as separate components, i.e. in two pieces or in two parts. This allows initially soldering the contacting element to the circuit board and fastening the contacting element with the help of a screw connection to the busbar only in a next step. In the case of busbars with relatively large cross-section, this simplifies the mounting on the circuit boards.

In detail, the electrical busbar device according to the invention includes a busbar that is electrically conductive and can thus be flowed through by an electric current, which can be in particular longitudinally shaped and can extend along a longitudinal direction. Further, the busbar device includes at least one contacting element that is configured separately with respect to the busbar and is connected both electrically and also mechanically to the busbar for connecting the electrical busbar to a circuit board. The contacting element is also configured so as to be electrically conductive. According to the invention, the at least one contacting element, preferentially a first end portion of this contacting element, is fastened to the busbar by means of a screw connection. A metal, in particular copper, is possible as electrically conductive material both for the busbar and/or the contacting element. Practically, the contacting element can be a flat shaped part. Starting out from the busbar, this facilitates bending over the contacting element in order to align the same with the circuit board.

In a preferred embodiment, the busbar is configured at least in two parts and includes a first and a second bar element, which are arranged on top of one another. With this further development, the at least one contacting element is arranged, in particular sandwich-like, between the two bar elements. In this way, the contacting element can be fixed to the busbar in a particularly mechanically stable manner. In addition to this, the electric current introduced into the contact element via the busbar can be divided over the two busbars which substantially reduces the thermal load at the transition from the busbar to the contacting element, in an ideal case even by half.

In another preferred embodiment, at least one contacting element is clamped between the two bar elements by means of the screw connection. By means of such a screw connection, a permanently stable fixing of the contacting element between the two bar elements of the busbar can be ensured. Since it is a releasable connection, a simple disassembly of the contacting element from the busbar is also possible.

In a preferred embodiment, at least one contacting element extends along an element extension direction. The contacting element is fastened with a, with respect to the element extension direction, first end portion to the busbar and comprises at a second end portion located opposite the first end portion multiple mounting elements for mounting and fixing the contacting element on or to the circuit board.

Particularly practically, the mounting elements can be configured as multiple protrusions projecting along the element extension direction and which are spaced apart from one another transversely to the element extension direction. The said mounting elements can also be pressed into the circuit board.

Regardless of this, the configuration of the mounting elements as protrusions facilitates soldering these mounting elements or protrusions to the circuit board.

In a further preferred embodiment, the busbar extends along a bar direction. In this embodiment, the at least one contacting element projects from the busbar laterally or transversely, in particular orthogonally, to the bar direction. Preferably, the bar direction can be arranged at an acute or right angle to the element extension direction.

According to a further advantageous further development of the busbar device according to the invention, the same can include at least two contacting elements which are arranged spaced apart from one another along the bar direction. This allows energising two or more circuit boards with a single busbar.

According to another advantageous further development, the screw connection includes the busbar, in particular through-openings formed in the two bar elements, and in the contacting elements. These through-openings in this further development are engaged through by a screw element for fixing the contacting element to the busbar. Preferably, at least one of these through-openings is formed as elongated hole. In this way, a position of the contacting element can be varied relative to the busbar along the bar direction.

Further, the invention relates to an arrangement having at least one circuit board and having at least one busbar device according to the invention introduced above. The advantages of the busbar device according to the invention explained above therefore apply also to the arrangement according to the invention. The at least one circuit board can be a PCB circuit board. With the arrangement according to the invention, the at least one contacting element is electrically connected to the circuit board by means of a solder connection. Apart from this, the contacting element can be mechanically crimped to the circuit board. With the arrangement according to the invention, the contacting element and the actual busbar are thus configured in two pieces or two parts just as with the busbar according to the invention. This allows during the course of the electrical wiring to initially solder the contacting element to the circuit board and in this way establish an electrical connection with the same. Only thereafter can the contacting element already fastened to the circuit board be connected to the actual busbar.

In a preferred embodiment of the arrangement according to the invention, the same includes a first circuit board and at least one second circuit board. Apart from this, the busbar device includes a first and a second contacting element. The at least one busbar of the busbar device is electrically connected to the first circuit board by means of the first contacting element and electrically connected to the second circuit board by means of the second contacting element. In this way, electrical or electronic power components can be supplied with energy via the electrical busbar on different circuit boards.

Further, the invention relates to a method for producing an arrangement according to the invention introduced above. The method according to the invention includes two measures a) and b). In a first measure a), a first contacting element of the busbar device is fastened to the circuit board by means of a solder connection, so that the contacting element is electrically connected to the circuit board. In a second measure b) carried out after the first measure a) in time, the contacting element is electrically and mechanically connected to this electrical busbar by means of a screw connection.

Further important features and advantages of the invention are obtained from the subclaims, from the drawings and from the associated figure description by way of the drawings.

It is to be understood that the features mentioned above and still to be explained in the following cannot only be used in the respective combination stated, but also in other combinations or by themselves without leaving the scope of the present invention.

Preferred exemplary embodiments of the invention are shown in the drawings and are explained in more detail in the following description, wherein same reference numbers relate to same or similar or functionally same components.

### BRIEF DESCRIPTION OF THE DRAWINGS

The drawings show, in each case schematically:

FIG. 1 an example of the busbar device according to the invention,

FIG. 2 an example of an arrangement according to the invention.

### DETAILED DESCRIPTION

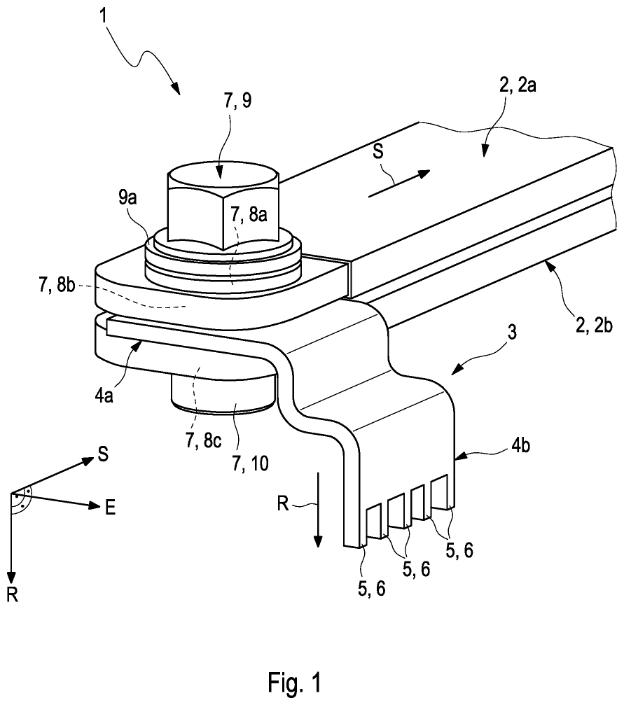

FIG. 1 illustrates in a perspective representation an example of a busbar device 1 according to the invention. The busbar device 1 includes according to FIG. 1 a busbar 2 that can be flowed through by an electric current, which for this purpose is configured so as to be electrically conductive. The electrically conductive material of the busbar 2 required for this purpose can be a metal, for example, copper. Further, the busbar device 1 includes an electrically conductive contacting element 3 that is formed separately and connected to the busbar 2 both electrically and also mechanically for connecting the electric busbar 2 to a circuit board (not shown) which does not belong to the busbar device 1. The electrically conductive material of the contacting element 3 can also be a metal, in particular copper.

According to FIG. 1, the busbar 2 is configured longitudinally shaped and the busbar 2 extends along a longitudinal direction, which in the following is referred to as “bar direction S”. The contacting element 3 projects from the busbar 2 transversely to the bar direction S. The contacting element 3 extends along an element extension direction E. Practically, the bar direction S can extend at an acute angle (not shown) or as shown in FIG. 1 at a right angle to the element extension direction E. Thus, the contacting element 3 projects transversely or orthogonally to the bar direction S from the busbar 2. As shown, the contacting element 3, from the busbar 2, can be curved or bent over in order to align it with the circuit board. Practically, the contacting element 3 can be a shaped sheet metal part. This facilitates bending over the contacting element 3.

In the example, a first end portion 4a of the contacting element 3 is fastened to the electrical busbar 2 by means of a screw connection 7. The busbar 2 is formed in two parts and includes a first and a second bar element 2a, 2b, which are stacked on top of one another or arranged on top of one another along a direction R. The direction R runs orthogonally both to the bar direction S and also to the element extension direction E.

In the region of the screw connection 7, the contacting element 3 is arranged sandwich-like between the two bar elements 2a, 2b and clamped between the two bar elements 2a, 2b by means of the screw connection 7. For this purpose, the screw connection 7 includes through-openings 8a, 8b, 8c formed in the two bar elements 2a, 2b of the busbar 2 and in the contacting element 3, which are aligned with one another. These through-openings 8a, 8b, 8c are engaged through by a screw element 9 of the screw connection 7. Here, the two bar elements 2a, 2b and the contacting element 3 arranged sandwich-like between the two bar elements 2a, 2b are pressed against one another by means of a threaded nut 10 of the screw connection 7 comprising an internal thread, into which the screw element 9 with its external thread is screwed, and a screw head 9a of the screw element 9. Thus, the contacting element 3 is fixed on the busbar 2 as desired.

It is conceivable to form the through-opening 8b formed in the contacting element 3 as elongated hole (not shown). In this way, a position of the contacting element 3 can be varied relative to the busbar 2 along the bar direction S.

According to FIG. 1, the contacting element 3 can comprise on a second end portion 4b located opposite the first end portion 4a along the element extension direction E, multiple mounting elements 5 for fixing the contacting element 3 on or to a circuit board (not shown in the FIG. 1). Like the entire contacting element, the mounting elements 5 are formed so as to be electrically conductive. The mounting elements 5 can be formed integrally on the contacting element 3, which means that the mounting elements 5 and the contacting elements 3 are formed in one piece and material-uniformly. The mounting elements 5 can, as shown, be formed by multiple protrusions 6 which extend along the direction R. The individual mounting elements 5 or protrusions 6 are arranged spaced apart from one another.

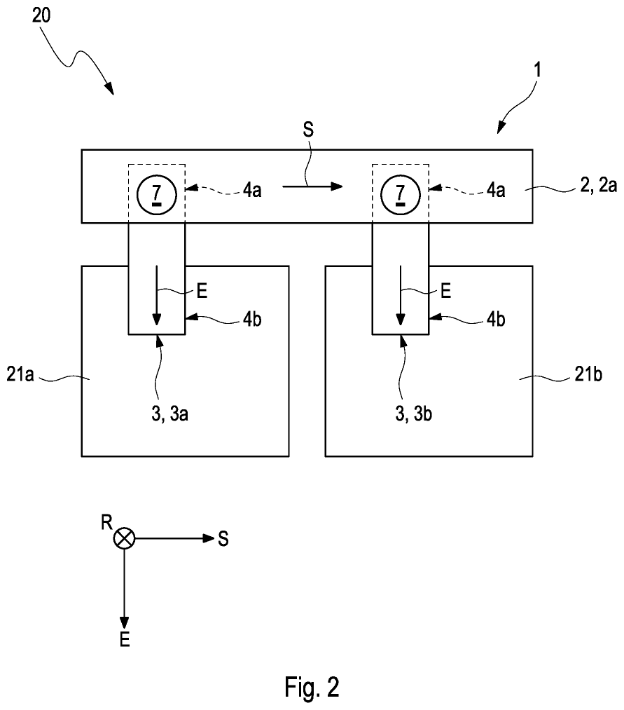

FIG. 2 shows in a rough schematic highly simplified representation an example of an arrangement 20 according to the invention. FIG. 2 is a plan view of the arrangement 20 along the direction R. The arrangement 20 includes a first and a second circuit board 21a, 21b and a busbar device 1 according to the invention. On the circuit boards 21a, 21b, electrical and electronic components can be arranged in each case (not shown). These components can be in particular electrical power components, in particular on semi-conductor bays, for example power components, in particular power amplifiers. The power components can be or include for example field effect transistors.

In the arrangement 20 shown in FIG. 2, the busbar device 1 includes two contacting elements 3a, 3b, 3 arranged spaced apart from one another along the bar direction S. The busbar 2 of the busbar device 1 is electrically connected to the first circuit board 21a by means of a first contacting element 3a, 3 and electrically connected to the second circuit board 21b by means of a second contacting element 3b, 3. The said electrical connection can each be realised by means of a solder connection.

1. An electrical busbar device, comprising
an electrically conductive busbar for being flowed through by an electric current;
at least one contacting element structured separately with respect to the busbar and connected electrically and mechanically to the busbar, the at least one contacting element structured to be electrically conductive for connecting the busbar to a circuit board; and
wherein the at least one contacting element is fastened to the busbar via a screw connection and electrically connected to the busbar.

2. The busbar device according to claim 1, wherein:
the busbar includes at least in two parts a first bar element and a second bar element that are arranged on top of one another,
the at least one contacting element is arranged sandwich-like between the first bar element and the second bar element.

3. The busbar device according to claim 2, wherein the at least one contacting element has a first end portion that is clamped between the first bar element and the second bar element via the screw connection.

4. The busbar device according to claim 1, wherein the at least one contacting element extends along an element extension direction and with a first end portion is fastened to the busbar and on a second end portion located opposite the first end portion with respect to the element extension direction comprises a plurality of mounting elements for fixing the at least one contacting element on the circuit board.

5. The busbar device according to claim 4, wherein the plurality of mounting elements are configured to be electrically conductive.

6. The busbar device according to claim 4, wherein the plurality of mounting elements are structured as protrusions projecting along the element extension direction and arranged spaced apart from one another transversely to the element extension direction.

7. The busbar device according to claim 1, wherein:
the busbar extends along a bar direction,
the at least one contacting element projects from the busbar transversely to the bar direction.

8. The busbar device according to claim 1, wherein at least two contacting elements are provided, which are arranged spaced apart from one another along the bar direction.

9. The busbar device according to claim 2, wherein:
the screw connection in the busbar includes through-openings disposed in the first bar element and the second bar element and in the at least one contacting element, the through-openings being engaged through by a screw element for fixing the at least one contacting element on the busbar, and
at least one of the through-openings is structured as elongated hole, so that a position of the at least one contacting element relative to the busbar is variable along the bar direction.

10. An arrangement, comprising:
at least one circuit board,
at least one busbar device, the at least one busbar device including:
an electrically conductive busbar for being flowed through by an electric current;
at least one contacting element structured separately with respect to the busbar and connected electrically and mechanically to the busbar, the at least one contacting element structured to be electrically conductive for connecting the busbar to the at least one circuit board;
wherein the at least one contacting element is fastened to the busbar via a screw connection and electrically connected to the busbar; and
wherein the at least one contacting element is electrically connected to the at least one circuit board via a solder connection.

11. The arrangement according to claim 10, wherein:
the at least one circuit board includes a first circuit board and at least one second circuit board,
the at least one contacting element includes a first contacting element and a second contacting element, and
the busbar is electrically connected to the first circuit board via the first contacting element and electrically connected to the at least one second circuit board via the second contacting element.

12. A method for producing an arrangement, the method comprising:
a) fastening at least one contacting element of a busbar device via a solder connection to a circuit board, so that the at least one contacting element after the fastening is electrically connected to the circuit board, and
b) electrically and mechanically connecting the at least one contacting element fastened to the circuit board to an electrical busbar of the busbar device via a screw connection.

13. The method according to claim 12, wherein electrically and mechanically contacting the at least one contacting element includes arranging the at least one contact element between a first bar element of the busbar and a second bar element of the busbar.

14. The arrangement according to claim 10, wherein:
the busbar includes at least in two parts a first bar element and a second bar element that are arranged on top of one another,
the at least one contacting element is arranged sandwich-like between the first bar element and the second bar element.

15. The arrangement according to claim 14, wherein the at least one contacting element has a first end portion that is clamped between the first bar element and the second bar element via the screw connection.

16. The arrangement according to claim 14, wherein:
the screw connection in the busbar includes through-openings disposed in the first bar element and the second bar element and in the at least one contacting element, the through-openings being engaged through by a screw element for fixing the at least one contacting element on the busbar, and
at least one of the through-openings is structured as elongated hole, so that a position of the at least one contacting element relative to the busbar is variable along the bar direction.

17. The arrangement according to claim 10, wherein the at least one contacting element extends along an element extension direction and with a first end portion is fastened to the busbar and on a second end portion located opposite the first end portion with respect to the element extension direction comprises a plurality of mounting elements for fixing the at least one contacting element on the circuit board.

18. The arrangement according to claim 17, wherein the plurality of mounting elements are configured to be electrically conductive.

19. The arrangement according to claim 17, wherein the plurality of mounting elements are structured as protrusions projecting along the element extension direction and arranged spaced apart from one another transversely to the element extension direction.

20. The arrangement according to claim 10, wherein:
the busbar extends along a bar direction, and
the at least one contacting element projects from the busbar transversely to the bar direction.
